(19) United States
(12) Patent Application Publication
(10) Pub. No.: US 2022/0158674 A1
(43) Pub. Date: May 19, 2022

(54) INTERFACE CIRCUIT, SYSTEM AND METHOD

(71) Applicant: SEMICONDUCTOR COMPONENTS INDUSTRIES, LLC, Phoenix, AZ (US)

(72) Inventors: Athar Ali KHAN P, Bangalore (IN); Manish Kumar VISHWAKARMA, Bangalore (IN)

(73) Assignee: SEMICONDUCTOR COMPONENTS INDUSTRIES, LLC, Phoenix, AZ (US)

(21) Appl. No.: 17/448,752

(22) Filed: Sep. 24, 2021

(30) Foreign Application Priority Data
Nov. 19, 2020 (IN) 202011050327

(51) Int. Cl. H04B 1/16; H03K 19/0175

(52) U.S. Cl. CPC H04B 1/1607; H03K 19/017509

(57) ABSTRACT

Interface circuit. Example interface circuits may be used for data transfer in accordance with the USB protocol version 3.2 or higher. Example interface circuits are configured to enable cooperation with a sink device and/or a host device having a lower supply voltage than the interface circuit, and reducing or preventing voltage spikes herein after power-on reset (POR) events. Thereto, the detection circuit for detection of a sink device downstream of the interface circuit is provided with a signal path for use during a first period after the POR event and having a resistance larger than a resistance used during detection of the said sink device.

### CROSS-REFERENCE TO RELATED APPLICATIONS

This application claims the benefit of Indian Patent Application No. 202011050327 filed Nov. 19, 2020, incorporated by reference herein as if reproduced in full below.

### FIELD

The present technology relates to an interface circuit, a system comprising an interface circuit, and a method of detecting a load using said interface circuit.

### BACKGROUND

Interface circuits are known in the related art to compensate for losses occurring during data transmission, such as losses due to transmission of data over signal lines between the host device and the sink device and vice versa. This particularly applies to transmission at higher data rates, such as 1 Gbps (1 Gigabyte/s) or more, or even 10 Gbps or more. In order to limit losses, the signal lines may be embodied as transmission lines, but that alone may not be a sufficient. The interface circuit may comprise a signal conditioner configured to improve signal quality. This may allow the signal to remain in compliance with the protocol, and the distance between a host device and a sink device may be extended.

The interface circuit may be embodied as an integrated circuit that is designed and manufactured separately from the integrated circuits in the host device and the sink device. Hence, not merely communication between the interface circuit and the host device and sink device need to be aligned, but it is furthermore the supply voltage of the interface circuit should not harm the host device or the sink device when the sink and/or host are operating at lower voltage than the interface circuit.

### SUMMARY

Various examples may provide an interface circuit, a system, and a method for detection of a load, such as a sink device or a host device. The system may involve a system configured for transmission of data between a host device and a sink device to be plugged in according to the Universal Serial Bus (USB) protocol, and more particularly according to versions 3.2 and higher.

In accordance with one aspect, the interface circuit is provided wherein a detection circuit for detection of the load comprises a first, second, and third signal path that are configured to be used in different usage modes of the system. In some examples, the first signal path is configured for use during a power-on reset (POR). The second signal path is configured for use during a first period after a POR event. The third signal path is configured for use during a second period in which it is to be detected whether the load connected to the system. In some cases, the second signal path has a higher resistance than the third signal path. The resistance of third signal path may be selected to distinguish between plug and unplug conditions.

In accordance with a further aspect, a system is provided comprising such an interface circuit, and furthermore a host device and a sink device configured for plugging into the system. The interface circuit may be used as a re-driver for a transmission from host device to sink device, and vice versa.

In accordance a further aspect, a method is provided for detecting a load. The example method comprises: in a first period after power on reset, delaying load detection; detecting in a second period after the first period connection or disconnection of a load (e.g., a sink device) coupled to the interface circuit via a pair of USB lines; and providing an indicator to a host device on disconnection or connection.

In accordance with a further aspect, an interface circuit is provided comprising: a signal conditioner; a first detection circuit for detection of an input signal; and a second detection circuit for detection of a load. The second detection circuit comprises: a voltage transfer slow down circuit for delaying voltage transfer after a POR event. The voltage transfer slow down circuit may comprise a selectively openable current path with a resistance to suppress voltage spikes. The resistance may be provided as a single resistor, a resistive network, or a set of parallel resistors. The resistance may be a resistance value of at least four times the resistance for load detection, such as a resistance between 5 and 15 times the resistance for load detection, for instance between 7 and 10 ties the resistance for load detection.

### BRIEF DESCRIPTION OF THE DRAWINGS

A more complete understanding may be derived by referring to the detailed description when considered in connection with the following illustrative figures. In the following figures, like reference numbers refer to similar elements and steps throughout the figures.

FIG. 1 is a schematic diagram of a system according to a first embodiment;

FIG. 2 is a schematic diagram of a system according to the first embodiment, indicating more details of the interface circuit;

FIG. 3 is a schematic diagram of an interface circuit according to a second embodiment;

FIG. 4 is a schematic diagram of the second detection circuit or “Receiver Detect” in the interface circuit;

FIG. 5 is a schematic diagram of the second detection circuit in combination with capacitors, transmission line, and signal branches on the sink side;

FIG. 6 is a graph indicating a supplied voltage as a function of time for a related-art device; and

FIG. 7 is a graph indicating a supplied voltage as a function of time in accordance with example embodiments.

### DETAILED DESCRIPTION

The present technology may be described in terms of functional block components and various processing steps. Such functional blocks may be realized by any number of components configured to perform the specified functions and achieve the various results. For example, the present technology may employ various voltage sensors, current sensors, coulomb counters, logic gates, timers, memory devices, signal converters, semiconductor devices, such as transistors and capacitors, and the like, which may carry out a variety of functions.

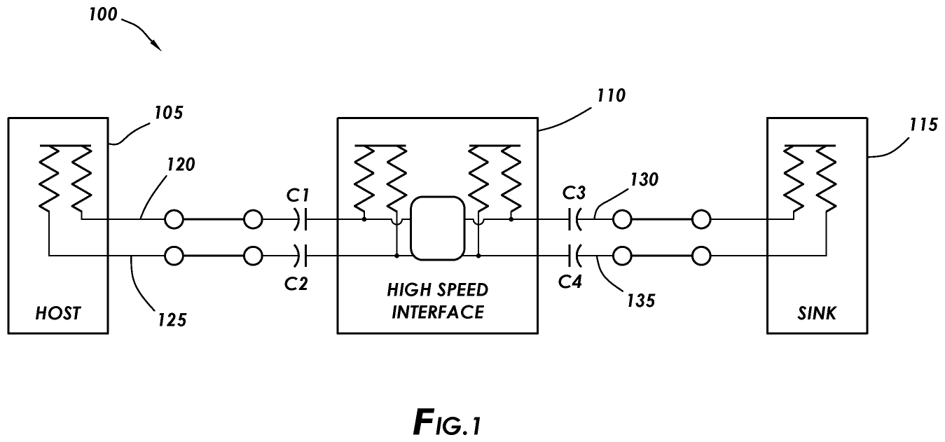

Methods and apparatus for an interface according to various aspects of the present technology may operate in conjunction with any suitable communication system. For example, and referring to FIG. 1, an example system 100 may comprise a host device 105 (e.g., a source device), an interface circuit 110, and a sink device 115. According various examples, the host device 105 and interface circuit 110 are connected by a transmission line system, such as a transmission line 120 and a transmission line 125, and a coupling capacitor, such as coupling capacitors C1, C2. Furthermore, the interface circuit 110 and the sink device 115 may be connected by a transmission line system, such as a transmission line 130 and a transmission line 135, and a coupling capacitor, such as coupling capacitors C3, C4. Accordingly, the host device 105 and the sink device 115 are electrically and communicatively coupled to each other via the interface circuit 110. The transmission line systems may comprise any suitable communication lines, buses, links, wires, cables, and the like for transferring data.

The interface circuit 110 may provide high-speed communication (data transmission) at a low voltage using shared input/output (I/O) pads. For example, the interface circuit 110 may be configured to perform at 1.8 volts for data rates of 5 Gbps (gigabits per second), 8.1 Gbps, and 10 Gbps. The interface circuit 110 may be capable of operating according to Universal Serial Bus (USB) 3.2 SuperSpeed Plus protocol, for example, completing related transmission and reception compliance testing at 10 Gbps. According to some examples, the interface circuit 110 may be implemented as a linear re-driver for multi-protocol applications, such as USB and/or DisplayPort. According to various examples, the interface circuit 110 may selectively bias various terminals to achieve a desired operation. According to various examples, the interface circuit 110 may operate according to various modes, such as a high-speed mode and a power-saving mode.

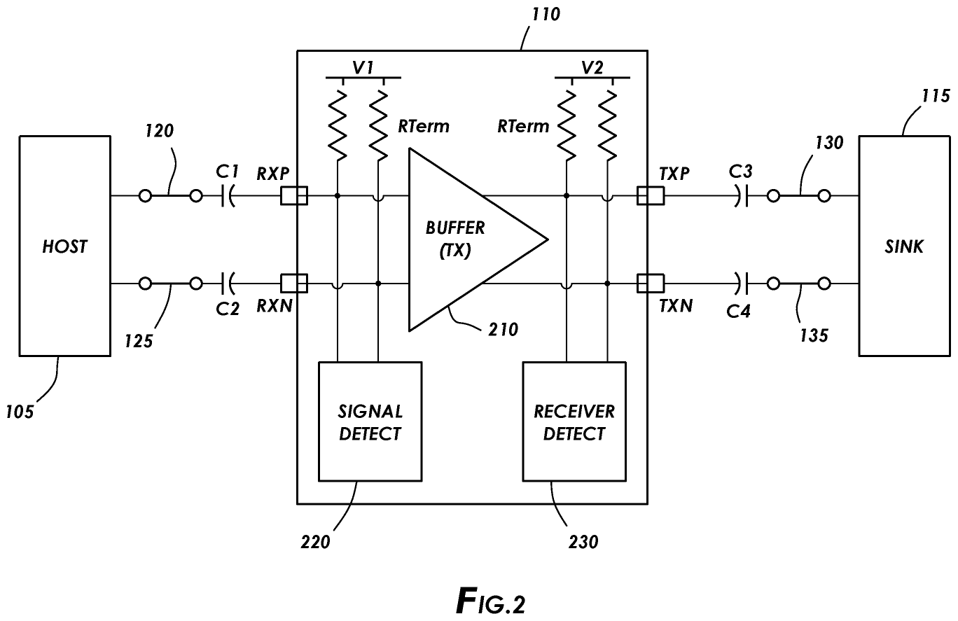

Referring to FIGS. 1 and 2, various examples of the interface circuit 110 may comprise a channel connected to a first pair of Input/Output (I/O) pads RXP, RXN and a second pair of I/O pads TXP, TXN. The first pair of I/O pads are “Receive” pads, as they are configured as input pads for receiving a signal from the host device 105. Correspondingly, the second pair of I/O pads TXP, TXN are “Transmit” pads, as they are configured as output pads through which conditioned signals are transmitted from the interface circuit 110.

FIG. 2 shows a schematic view the system as shown in FIG. 1, with more details on the interface circuit 110. In particular, the example interface circuit 110 may comprise a signal conditioner 210, a first detection circuit 220, and a second detection circuit 230. Termination resistances RTerm are provided, which are used for high speed transfer. The signal conditioner 210 in this example is a buffer, and is configured to buffer signals arriving from the host device 105 at input contact pads RXP, RXN and to be transmitted to the sink device 115 via output contact pads TXP, TXN. The signal conditioner 210 may be used because the transmission lines 120, 125, 130, 135 may have considerable length, and data transfer over the transmission lines may lead to losses resulting in reduced signal-to-noise ratio. The signal conditioner 210 may comprise an amplifier. The first detection circuit 220 and the second detection circuits 230 serve to detect when the signal conditioner 210 is to be in an active mode so as to enable data transfer. Thereto, the first detection circuit 220 is configured to detect the input signal coming from the hose device 105. If the input signal is valid and/or above a predefined threshold, then the signal conditioner 210 is activated. The second detection circuit 230 is configured to detect the presence or absence of a sink device 115. In one example, the second detection circuit 230 is configured to detect a resistance.

In a first period after a power-on reset (POR) event, the second detection circuit 230 is configured to reduce or eliminate high voltage surges at host/sink devices. It has been observed in investigations of the inventors that voltage spikes occur particularly in a period directly after a POR event. It is believed that the voltage spikes are due to the coupling capacitors C3 and C4 acting as a short circuit, in combination with one or more of the resistors internal and/or external to the interface circuit 110. According to the present technology, the voltage transfer to the sink device 115 is slowed, and the risk of voltage spikes exceeding a limit at the sink device 115 is significantly reduced. This is particularly embodied in that the second detection circuit 230 is provided with a current path configured for use during the first period after the POR event and having a resistance sufficient to dampen voltage spikes.

In a second period after the POR event, the second detection circuit 230 is configured to detect the termination impedance presented by sink device 115. If the resistance is low, for instance 50 Ohms, this implies that the sink device 115 is able to receive data. The signal conditioner 210 may then be enabled to connect its low resistive termination RTerm at its input, therewith enabling the host device 105 to transmit data to the sink device 115. In the second period, the second detection circuit 230 is furthermore configured to detect an increase of a resistance and/or a predefined high resistance. For instance, such predefined high resistance may be a resistance of more than 25 kOhm. If the second detection circuit 230 detects such high resistance or an increase in resistance, the signal conditioner 210 disconnects its low resistive termination at its input. The disconnection of the low resistive termination is used by the host device 105 as an indicative signal to disconnect.

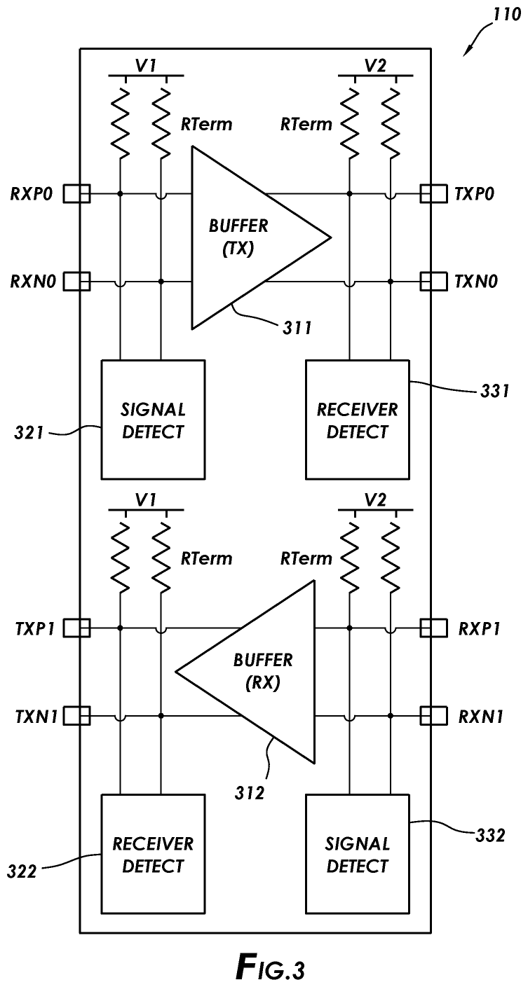

FIG. 3 shows a further embodiment of an interface circuit 110. Herein, the interface circuit 110 is provided with interfacing functionality for signal transmission from a host device 105 (FIG. 1) to a sink device 115 (FIG. 1) and from the sink device 115 to the host device 105. In particular, for data transmission from the host device 105 (FIG. 1) to the sink device 115 (FIG. 1), the example interface circuit 110 of FIG. 3 comprises a signal conditioner 311, a signal detect circuit 321, and a receiver detect circuit 322. Sets of input contact pads RXP0 and RXN0, and output contact pads TXP0, and TXN0 are provided. For data transmission from the sink device 115 to the host device 105, the example interface circuit 110 of FIG. 3 comprises a signal conditioner 312, a signal detection circuit 331, and a receiver detect circuit 322. Sets of input contact pads RXP1 and RXN1, and output contact pads TXP1, and TXN1 are provided. Each interfacing functionality may be identical or may be configured specifically for one direction. In the following, the present technology will be elucidated for the case that the second detection circuit is configured to detect presence or absence of the sink device 115.

Referring again to FIG. 2 as representative, as the interface circuit 110 may be fabricated separately from the host device 105 and the sink device 115, the interface circuit 110 may be made in different technology resulting in different supply voltages. Particularly, the sink device 115 and/or the host device 105 may be designed to operate at a lower supply voltage than the interface circuit 110. It has been found during investigations that, when the second detection circuit 230 sends out detection signals to detect a resistance and/or a change in resistance at or towards the sink device 115, voltage spikes may occur that exceed the accepted supply voltage of a sink device 115. For instance, the supply voltage of the interface circuit 110 may be 1.8 Volt, whereas the accepted supply voltage of the sink device 115 may be 1.0 Volt.

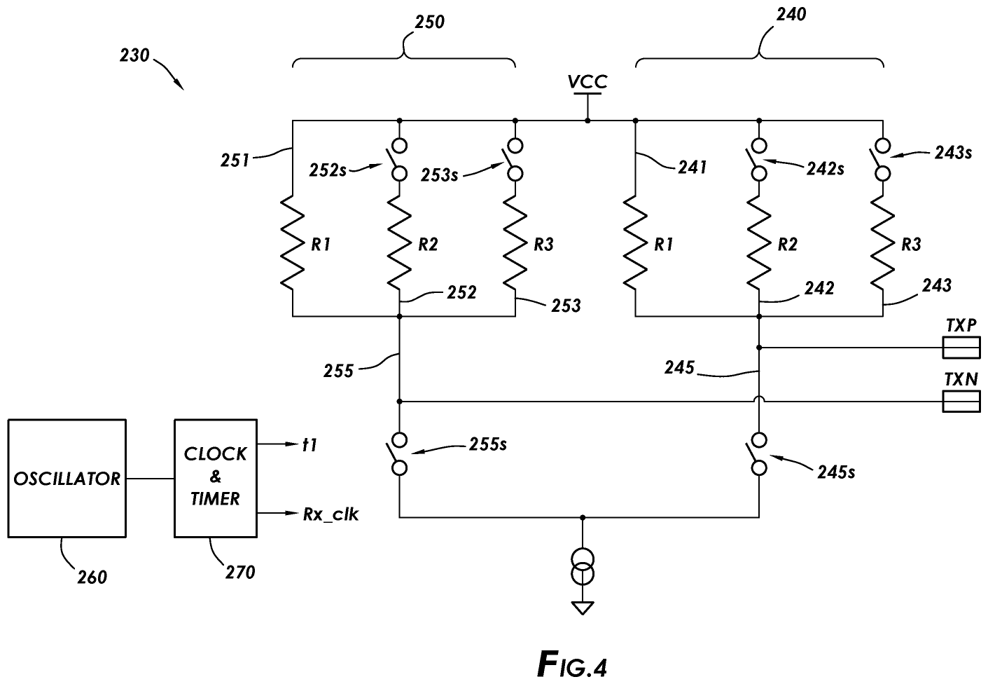

FIG. 4 shows a schematic diagram of the second detection circuit 230 according a first embodiment. Herein the second detection circuit 230 comprises a first signal path or first current path 241 provided with a resistor R1, a second signal path or second current path 242 with a resistor R2, and a third signal path or third current path 243 with a resistor R3. The second current path 242 is provided with a switch 242S. The third current path 243 is provide with a switch 243S. The example first current path 241 does not include a switch, but in other examples a switch may be included in the first current path 241. The first current path 241 is configured as a current path during POR mode. Thereto, the resistor R1 is suitably chosen to be large, for instance 0.5-5 MOhm. The second current path 242 is configured as a current path during a first period after the POR event. In one embodiment, such first period has a duration of 100 ms. However, the duration may be subject to change depending upon the value of C3, R5, and R3, and could be one second in some cases. The second current path 242 may be used before the actual detection starts, the second current path to reduce or avoid high voltage surge at sink device 115. The third current path 243 is configured as a current path during a second period during the POR mode after the POR event. Such a second period may start after the first period. It is however not excluded that any further period will be present between the first and the second period. During the example second period, the second detection circuit 230 is configured to detect a termination resistance or a change in resistance at its outputs. The current paths 241, 242, and 243 merge into a common or single current path 245 that is coupled to an output pad TXP. In one example, the resistance value of resistor R2 is larger than the resistance value of resistor R3. And in some examples, both are smaller than the resistance value of resistor R1.

In order that the second current path 242 is used, the switch 242S is closed and the switch 243S is opened. The switch 242S is driven by means of a timing signal t1 originating from a clock & timer circuit 270 implemented in the interface circuit 110. Input to this clock & timer circuit 270 is an oscillator 260, which is may be an on-chip oscillator, but could alternatively be a discrete oscillator. The switch 243S is driven in this implementation by a clock signal Rx_clk, and the switch 243S will be closed or conductive in order to use the third current path 243. While the example of FIG. 4 includes the second current path 242 between the first, high-ohmic current path 241 and the third, low-ohmic current path 243 for load detection, additional current paths may be present, each having a resistance intermediate between that of the first current path 241 and the third current path 243. Furthermore, rather than a plurality of intermediate current paths between the first current path 241 and the third current path 243, the second current path 242 may be configured as a resistive network.

The resistance value of the resistor R2 of the second current path 242 may be at least four times the resistance value of resistor R3, in some cases between 5 and 15 times the resistance value of resistor R3, an in other cases between 7 and 10 times the value for R3. It follows that the current in the first period is reduced relative to the current in the second period. For instance the current in the first period may be reduced with a factor R2/R3, with a margin or tolerance of ±50%.

In the illustrated example, the second detection circuit 230 is configured for transmission of detection signals via either the negative transmit output pad TXN or the positive transmit output pad TXP. Thereto, the second detection circuit 230 comprises a first set of current paths (hereafter first set 240) and a second set of current paths (hereafter second set 250), which are arranged in parallel and which may be identical in design. Thus, the second set 250 comprises a first current path 251, a second current path 252, and a third current path 253 with resistors R1, R2, and R3, respectively, and with switches 252S and 253S in the second and third current path 252 and 253, respectively. The current paths 251, 252, and 253 of the second set 250 are coupled to a common or single current path 255 that is connected to an output pad TXN. The single current paths 245 and 255 are each provided with a switch 245S and 255S, respectively. Therewith, either the first set 240 or the second set 250 can be selectively turned on or off. Furthermore, these switches 245S and 255S enable to switch off the second detection circuit 230 entirely, if so desired. The switches used in the second detection circuit 230 are suitably embodied as transistors, such as CMOS transistors or bipolar transistors.

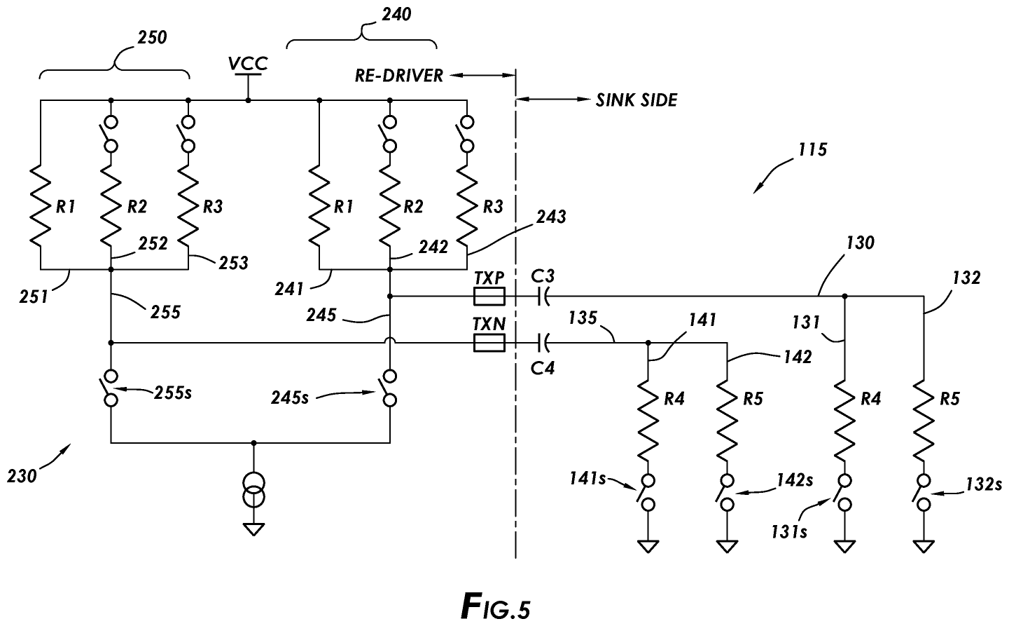

FIG. 5 shows the second detection circuit 230 in combination with circuitry associated with the sink device 115. The transmission line 130 is coupled to a first branch 131 and a second branch 132. The transmission line 135 is coupled to a first branch 141 and a second branch 142. These branches may be implemented within the sink device 115, although it is not excluded that they would be external to the sink device 115. The first branch 131 comprises a resistor R4 and a switch 131S. The first branch 141 comprises a resistor R4 (e.g., having the same resistance as R4 in the first branch 131) and a switch 141S. The second branch 132 comprises a resistor R5 and a switch 132S. The second branch 142 comprises a resistor R5 (e.g., having the same resistance as R5 in the second branch 132) and a switch 142S. The resistors R4 are each a low resistance, for instance 50 Ohm. The resistors R5 are each a higher resistance, for instance 50-400 kOhm. In some cases, the resistance values of resistors R2 are chosen to be about equal to the resistance values of resistors R5. It is however not excluded that the resistance value of resistor R2 is different than the resistor value of resistor R5 depending upon the supply of the re-driver and host/sink devices. The resistance values of the resistors R5 may be chosen to meet the specification of USB protocol version 3.1. In one example, the resistance values of resistors R4 are smaller than the resistance values of resistor R3. The switches 131S, 141S are driven closed only when the sink device 115 is active, therewith enabling a low-resistance path via the first branches 131 and 141. The switches 132S, 142S are driven closed when the sink device 115 is in a power saving mode, in a power-up mode, or in a power-down mode.

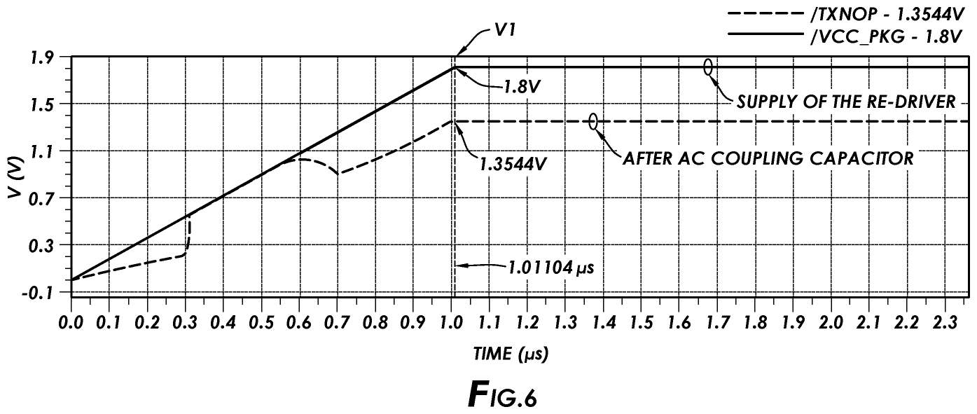

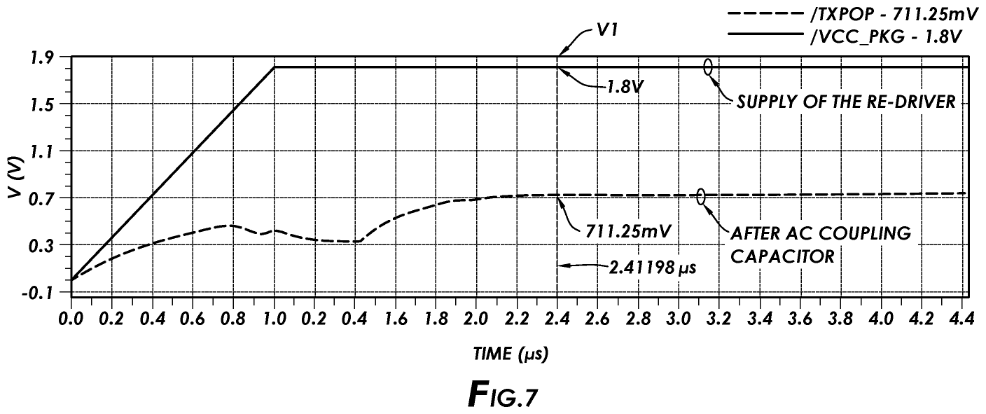

FIGS. 6 and 7 show two corresponding graphs in which the voltage across the transmission lines 130 and 135 (and thus voltage to the sink device 115), is shown as a function of time after a power on event in microseconds (μs). FIG. 6 shows the result for a related-art reference device when the TXP and TXN are terminated with R5. FIG. 7 shows the result for an interface circuit with an example second detection circuit 230 when the TXP and TXN are terminated with R5. The supply voltage of the interface circuit 110 in both cases 1.8V.

Referring initially to FIG. 6, after power on event the supply voltage rises (during the POR mode) to 1.8V in approximately 1 μs (in this example, μs is considered as ramp time for supply voltage but can higher or lower). The voltage across the transmission lines 130 and 135 rises to 1.35V in the same time frame. The reduction from 1.8 to 1.35V is due to resistance value used to detect the termination resistance of the sink device. Moreover, in rising to 1.35V, the voltage applied to the sink device 115 by way of the transmission lines 130 and 135 exceeds a 1V limit set by various standards.

Referring now to FIG. 7, by contrast, in a system implemented in accordance with the various example cases the voltage across the transmission lines 130 and 135 rises to only about 0.71V, and it takes approximately 2.4 μs to arrive at this supply level. As a consequence, coupling voltage applied to the sink device 115 does not exceed the 1V limit. Hence, there is a 40% margin to accommodate voltage spikes without exceeding the 1V limit applicable to the sink device. Additionally, it is visible upon comparison of FIGS. 6 and 7 that the voltage transfer has slowed down. In the related-art of FIG. 6, the maximum voltage level is reached in 1 μs, and in the example shown in FIG. 7, the maximum voltage level is reached only after 2.4 μs. In example cases, during the first period, a current is used at a lower level than during the second period, so that a product of resistance and current in the first period and the second period are equal to each other with a predetermined range of tolerance.

In the foregoing description, the technology has been described with reference to specific example embodiments. The particular implementations shown and described are illustrative of the technology and its best mode and are not intended to otherwise limit the scope in any way. Indeed, for the sake of brevity, manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An interface circuit comprising:
a signal conditioner;
a first detection circuit for detection of an input signal;
a second detection circuit for detection of a load, the second detection circuit comprising:
a first signal path for use during a power-on reset (POR) mode;
a second signal path for use during a first period following a POR mode;
a third signal path for use during a second period after the first period, during which second period the second detection circuit is configured to detect a load; and
wherein the second signal path has a resistance smaller than the first signal path and larger than the third signal path.

2. The interface circuit of claim 1, wherein the first, second, and third signal paths are arranged in parallel.

3. The interface circuit of claim 2, further comprising further signal paths arranged in parallel, which further signal paths have a resistance intermediate to that of the first signal path and the third signal path, and wherein said further signal paths are configured for use during the first period or part thereof.

4. The interface circuit of claim 2, wherein each of the second and the third signal path is provided with a switch for selectively being conductive at a predefined use period.

5. The interface circuit of claim 2, wherein a common signal path is arranged in series with the first, second, and third signal paths, and which common signal path is provided with a switch.

6. The interface circuit of claim 2, wherein the second detection circuit comprises a first set comprising the first, second, and third signal paths, and a second set comprising a fourth, fifth, and sixth signal paths, wherein the first set is coupled to a first output pad configured for transmission of a positive signal (TXP), and the second set is coupled to a second output pad configured for transmission of a negative signal (TXN).

7. The interface circuit of claim 1, wherein the signal conditioner is a buffer circuit comprising an amplifier.

8. The interface circuit of claim 1, being a bi-directional interface circuit and provided with a signal conditioner for each direction of signal transmission.

9. The interface circuit of claim 1, wherein the interface circuit is configured for operation as a Universal Serial Bus (USB) re-driver.

10. The interface circuit of claim 1, being configured for operation with a supply voltage that is higher than a predefined supply voltage of a host device and/or a sink device between which the interface circuit is to be coupled.

11. A communication system comprising:
a host device comprising a first and a second signal lines;
a sink device;
an interface circuit coupled between sink device and the first and second signal lines, the interface circuit comprises a signal conditioner, a first detection circuit for detection of an input signal, and a second detection circuit for detection of a load, the first detection circuit is configured to detect an input signal from either the host device or the sink device, and the second detection circuit is configured to detect an available signal path to the sink device or the host device;
wherein the second detection circuit comprises:
a first signal path for use during a power-on reset (POR) mode;
a second signal path for use during a first period following a POR mode, during which the second detection circuit is configured to avoid high voltage surge at host and/or sink devices during receive detection; and
a third signal path for use during a second period after the first period, during which second period the second detection circuit is configured to identify a connection or disconnection of a load;
wherein the second signal path has a resistance smaller than the first signal path and larger than the third signal path.

12. The communication system of claim 11, wherein the interface circuit is configured for operation with a supply voltage that is higher than a predefined supply voltage of the host device and/or the sink device.

13. The communication system of claim 11, further comprising capacitors disposed one each in the first and second signal lines downstream of the interface circuit.

14. The communication system of claim 11, wherein the first, second, and third signal path of the second detection circuit are arranged in parallel, and wherein a common signal path is arranged in series with the parallel signal paths, which common signal path is provided with a switch.

15. The communication system as claimed in claim 14, wherein the second detection circuit comprises a first set comprising the first, second, and third signal paths, and a second set comprising a fourth, fifth, and sixth signal paths, wherein the first set is coupled to a first output pad of the interface circuit associated with the first signal line, and the second set is coupled to a second output pad of the interface circuit associated with the second signal line.

16. The communication system of claim 11, wherein the first and the second signal lines are provided, downstream of the interface circuit, with a first and a second branch that may be selectively opened and closed, and wherein the first branch is configured for use in an active mode and provided with a lower resistance than the second branch.

17. The communication system of claim 11, wherein the sink device is removable by a user.

18. The communication system of claim 11, configured for use in accordance with a Universal Serial Bus (USB) protocol of version 3.2 or higher.

19. A method of detecting a presence of a load coupled to an interface circuit after a Power On Reset (POR) event, the method comprising:
delaying, by the interface circuit, load detection in a first period after the POR event, the load coupled to the interface circuit via a pair of transmission lines, a signal path used by the interface circuit in the first period has a first resistance;
detecting, by the interface circuit in a second period after the POR event, a resistance value of the load coupled to the interface circuit, the signal path used by the interface circuit in the second period having second resistance lower than the first resistance; and
providing, by the interface circuit, an indication to second device coupled to the interface circuit, the indication being an indication of disconnection or connection of the load by disabling or enabling an input termination coupled to second device.

20. The method of claim 19, wherein during the first period, a current is used at a lower level than during the second period, so that a product of resistance and current in the first period and the second period are equal to each other with a predetermined range of tolerance.
